(19) United States
(12) Patent Application Publication
(10) Pub. No.: US 2002/0053921 A1
(43) Pub. Date: May 9, 2002

(54) Semiconductor test apparatus and control method therefor

(75) Inventor: Hiroshi Koshiba, Tokyo (JP)

Correspondence Address: DARBY & DARBY, 805 THIRD AVENUE, 27TH FLR., NEW YORK, NY, 10022, US

(73) Assignee: Ando Electric Co., Ltd.

(21) Appl. No.: 09/975,835

(22) Filed: Oct. 11, 2001

(30) Foreign Application Priority Data
Oct. 18, 2000 (JP) 2000-317871

(51) Int. Cl. G01R 31/26

(52) U.S. Cl. 324/765

(57) ABSTRACT

The present invention provides a semiconductor test apparatus that can reduce the number of internal transfers of pattern files to a minimum. In the semiconductor test apparatus 11, the control unit 10 produces a pattern file use frequency table in the pattern file use frequency table memory 18, and in a set of test in which a predetermined number of semiconductors to be tested are tested, the use frequency of the pattern files is obtained. In addition, the control unit 1 again reads out the pattern files based on the frequency of use that has been obtained, and rearrange the pattern files in the executive memory 17. In addition, the control unit 10 deletes the pattern files in ascending order of the frequency of use when the capacity of the memory becomes insufficient.

### BACKGROUND OF THE INVENTION

1. Field of the Invention

The present invention relates to a semiconductor test apparatus that optimally distributes pattern files necessary for the testing of the operation of the semiconductor to be tested (a semiconductor integrated circuit) in executive memory.

2. Description of the Related Art

In semiconductor test apparatuses, the pattern data necessary for carrying out the test of the semiconductor comprises the data applied to the semiconductor and the comparative data that, based on this applied data, evaluates the output data that is output from the semiconductor.

In addition, when carryout out the testing of the semiconductor, the semiconductor test apparatus reads the pattern files corresponding to this semiconductor from a high-capacity memory apparatus, and stores these in the memory of the test apparatus as pattern files.

Here, referring to FIG. 4, the manner in which the conventional semiconductor test apparatus controls these pattern files will be explained.

Before the start of the test, the control unit 40 stores the pattern files from an external memory apparatus (not illustrated) that are used in the testing of a plurality of types of semiconductors in the DISK 42 built into the semiconductor test apparatus 41.

Next, in the preparation stage of the test of the semiconductor, the control unit 40 transfers the pattern files for testing the type (type 1) of semiconductor that will be tested to the high-capacity buffer memory 43 of the semiconductor test apparatus 41 from the DISK apparatus 42 as pattern files having the same format as when stored in the DISK apparatus 42, and stores them.

Normally, during the test of the semiconductor, a plurality of pattern files corresponding to the test items for each type of semiconductor is prepared, and as a result, a plurality of pattern files is stored in the DISK 42 and the buffer memory 43.

In the state wherein the pattern files are stored in the buffer memory 43 as described above, when the test of the semiconductor begins, the test progresses up to the stage in which a specific pattern file is used among the test items that test a specific operation of the semiconductor.

At this time, the control unit 40 distributes pattern data used in the test and control data that controls the operation during the test from the pattern files that relate to specific test items.

In addition, the control unit 40 transfers this distributed data to the pattern memory 44, the MIC memory 45, and the SPG (Serial Pattern Generator) memory 46, which comprise the executive memory while the test of the semiconductor is being carried out.

Here, the pattern memory is memory for storing the pattern data for the test of the semiconductor, the MIC memory 45 is the memory for storing the control data that controls the operation of the semiconductor test apparatus, and the SPG memory is memory that stores the pattern data, which sends the pattern of a periodic clock to a terminal of a semiconductor.

This means that the data for the pattern files is distributed in each executive memory (comprising the pattern memory 44, the MIC memory 45, an the SPG memory 46), and the control unit 40 controls these files as linked data sets based on a specific algorithm.

Next, the file control algorithm in the above-mentioned executive memory (pattern memory 44, MIC memory 45, and SPG memory 46) according to the conventional technology will be explained referring to FIG. 5.

FIG. 5 is a flowchart that shows the operations of searching the pattern files, transferring the pattern files to the executive memory, and finally implementing the test based on pattern files for one among the test items for testing the semiconductor.

In step 51, for the semiconductor to be tested, the control unit 40 searches the pattern files to be used in testing the semiconductor in each executive memory, and in step 52 the control unit decides whether or not this pattern file is present in each executive memory.

As a result of this decision, in the case that the pattern file is already present in the executive memory, the processing jumps to step 5D, and the test of the semiconductor is started using this pattern file.

Here, in the case that the pattern file used in testing the semiconductor is not present, the control unit 40 distributes it by transferring the necessary pattern files to each executive memory from the buffer memory 43 according to the sequence from step 53 to step 5C.

In step 53, the control unit 40 finds whether or not the relevant pattern files are present in the buffer memory 43, and in the case that the pattern files are not stored in the buffer memory 43, the test of the semiconductor is discontinued by error processing.

In contrast, in the case that the pattern files are present in the buffer memory 43, in the sequence from step 55 to step 5A, the control unit 40 obtains the control information for each executive memory and confirms whether or not a capacity adequate for a transfer is available.

In the case that the capacity of any one among the executive memories is inadequate, in order to guarantee a capacity that will allow the transfer, the control unit 40 initializes the executive memories in step 5B, and erases all of the stored data. Specifically, initializing the executive memories means initializing the control information of each control memory. At this time, all of the pattern files stored therein appear to be erased.

Next, in step 5C, the control unit 40 again transfers the pattern files to be used in the test of the semiconductor to the executive memories, and after completing the transfer of the pattern files, begins the test of the semiconductor based on the pattern data in step 5D.

The transfer of the pattern files and the initialization of the executive memories are repeated, and the tests using all of the pattern files are carried out according to the file control algorithm for the executive memory that has been described above.

However, once transferred to the executive memories, all of the pattern files necessary for the test are transferred to the executive memories so that they can be managed as the pattern files until the initialization of the executive memories, and thereby after the second test, initialization of the executive memories and further transfers are not necessary, and the load during execution is reduced.

Furthermore, in recent years, in the testing of semiconductors, the test items and the test content has greatly increased due to the increased number of functions of the semiconductor itself, and the pattern files for the tests have become very large, there are few tests of semiconductors that can transfer all of the pattern files to the executive memory, the transfer of pattern files is repeated more than two times during the test, and thereby the efficiency of the test of the semiconductor deteriorates.

In addition, in the conventional semiconductor apparatus, the pattern files used in the test are transferred to the executive memories according to the order of execution of the test items irrespective of the frequency of use, and furthermore, in the case that there is insufficient free memory capacity, the simple algorithm of initializing all memory is used, and thus there is the drawback that high speed testing cannot be carried out.

This means that in order to provide a high speed test environment under the condition that the amount of data of the pattern files necessary for testing the semiconductor may exceed the memory capacity of the executive memory because the capacity of the executive memory is limited, an algorithm is required that retains the pattern files that are used with a high frequency in the executive memory, and that reduces to a minimum the pattern files that are transferred a plurality of times.

Generally, the testing of semiconductors uses a method wherein a semiconductor is categorized as defective in the case that even one among the many test items fails, and in consideration of the throughput of the testing, the test is discontinued when any test item fails, and the test of the next semiconductor is begun.

Therefore, the frequency of use of a pattern file can change depending on the defect rate for each semiconductor, and thus uniformly assigning an algorithm that decides the frequency of use of a pattern file in the semiconductor test apparatus is difficult.

In consideration of the background described above, it is an object of the present invention to provide a semiconductor test apparatus that reduces to a minimum the number of the internal transfers of pattern files, and can reduce the testing time of the semiconductor.

### SUMMARY OF THE INVENTION

The semiconductor test apparatus according to the present invention tests the operation of a semiconductor based on a plurality of pattern data and is characterized in comprising a counter device that counts the number of times pattern data is used for each pattern file and a control unit that produces a pattern file use frequency table showing the relationship between each of the files and the number of times the files are used, and stores this pattern file use frequency table in the memory.

The semiconductor test apparatus of the present invention is characterized in that the counting device counts the number of times pattern data is used in the test of a preset number of semiconductors.

The semiconductor test apparatus of the present invention is characterized in that the control unit loads the pattern files in descending order of the use frequency table after producing the pattern file use frequency table.

The semiconductor test apparatus of the present invention is characterized in that the control unit deletes the pattern files beginning with those having a low use frequency in the case that the capacity of the executive memory is in sufficient when transferring pattern files to the executive memories.

The control method of the semiconductor test apparatus of the present invention that tests the operation of a semiconductor based on a plurality of pattern data is characterized in providing a counting step in which the number of times pattern data is used is counted for each pattern file and a storage step in which a pattern file use frequency table that shows the relationship between each file and the number of times this file is used, and stores this pattern file use frequency table in the memory.

The control method of the semiconductor test apparatus of the present invention is characterized in that, in the counting step, the number of times pattern data is used in the test of a preset number of semiconductors is counted.

The control method of the semiconductor test apparatus of the present invention is characterized in that the storage step loads the pattern files in descending order of frequency of use based on this pattern file use frequency table after producing the pattern file use frequency table.

The control method of the semiconductor test apparatus of the present invention is characterized in that the storage step deletes the pattern in ascending order frequency of use in the case that the capacity of the executive memory is in sufficient when transferring pattern files to the executive memories.

### BRIEF DESCRIPTION OF THE DRAWINGS

FIG. 1 is a block diagram showing the structure of the semiconductor test apparatus according to an embodiment of the present invention.

FIG. 2 is a flowchart showing the production of the pattern file use table of the present invention, and the redistribution of the files.

FIG. 3 is a flowchart showing the transfer format of the pattern file according to the present invention.

FIG. 4 is a drawing for explaining the control structure of the pattern files according to a conventional example.

FIG. 5 is a flowchart showing the transfer format of the pattern files according to a conventional example.

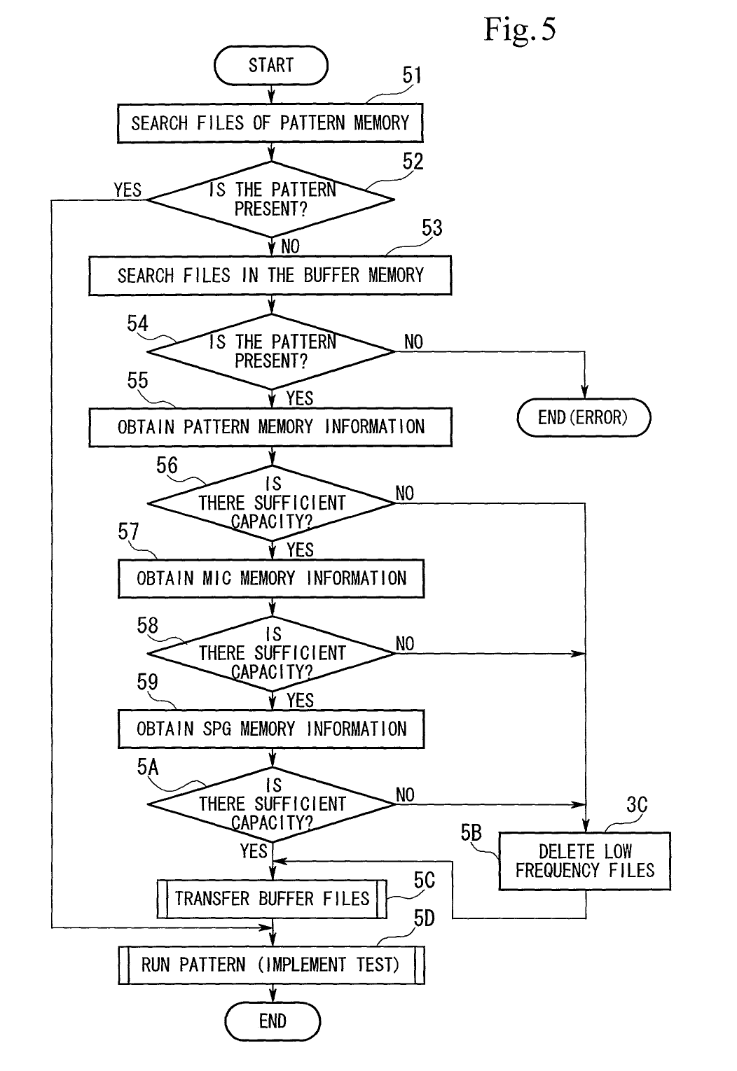

### DETAILED DESCRIPTION OF THE INVENTION

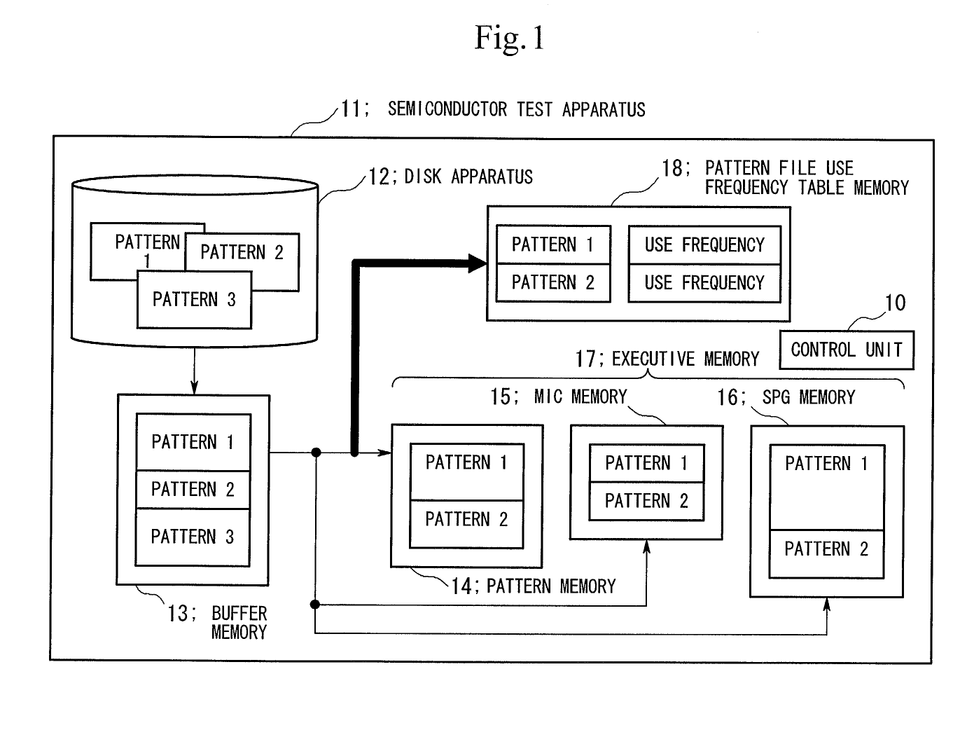

Below, an embodiment of the present invention will be explained referring to the drawings. FIG. 1 is a block diagram showing the structure of the semiconductor test apparatus according to an embodiment of the present invention. In this figure, the disk apparatus 12 stores pattern files for a plurality of types of semiconductors that the control unit 10 reads in from an external memory apparatus.

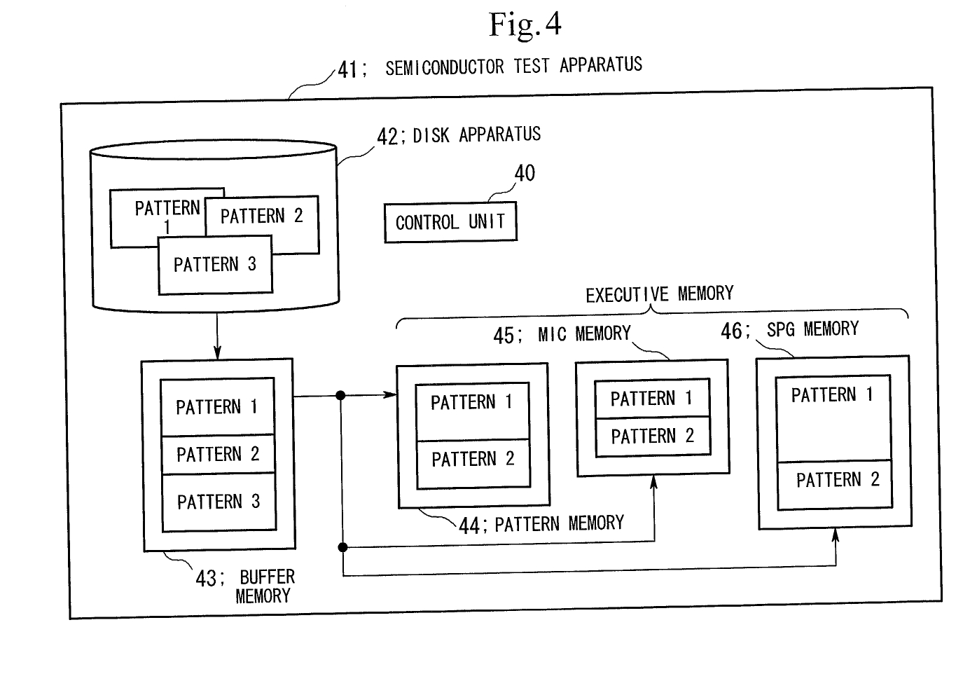

The buffer memory 13 stores the pattern files to be used in the test of the semiconductor that are read out from the disk apparatus 12 by the control unit 10. The executive memory 17 is formed by the pattern memory 14, the MIC memory 15, and the SPG memory 16 and distributes and stores the pattern files. Here, the pattern memory 14, the MIC memory 15, and the SPG memory 16 are memories that are respectively identical to the pattern memory 44, the MIC memory 45, and the SPG memory 46 in FIG. 4.

The pattern file use frequency table storage unit 18 associates each pattern file and the number of times each pattern file is used, which is calculated by the control unit 10, and stores them.

In addition, the format by which the pattern files are controlled in the semiconductor test apparatus, that is, the format in which the pattern files are distributed and stored in each memory of the executive memory 17 from the disk apparatus 12, is identical to the conventional method already explained, and the explanation thereof will be omitted.

After the pattern files are stored, in the conventional method a test is carried out by applying the pattern data of the pattern files to the semiconductor that is the test object.

In contrast, in the present invention, because the frequency of use for each pattern file is found, in the step of testing a preset (specified) number of semiconductors that are the test objects, the frequency of use of each of the pattern files counted by the control unit is stored for each pattern file in the pattern file use frequency table of the pattern file use frequency table storage unit 18.

This preset number represents a number of samples that will reflect the frequency of use of the pattern files among the total number of semiconductors that are the test object.

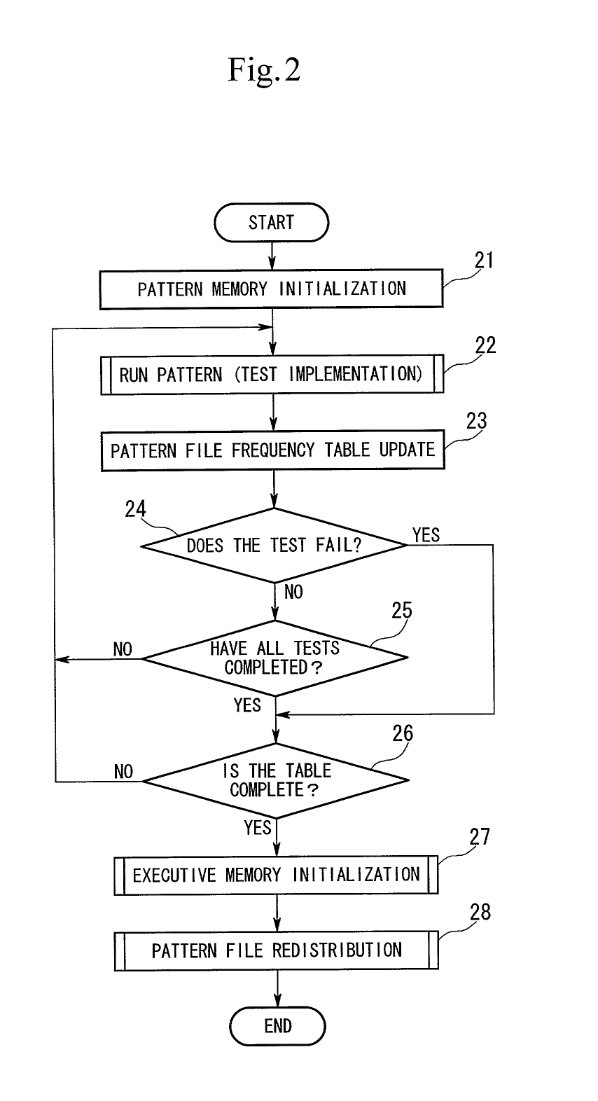

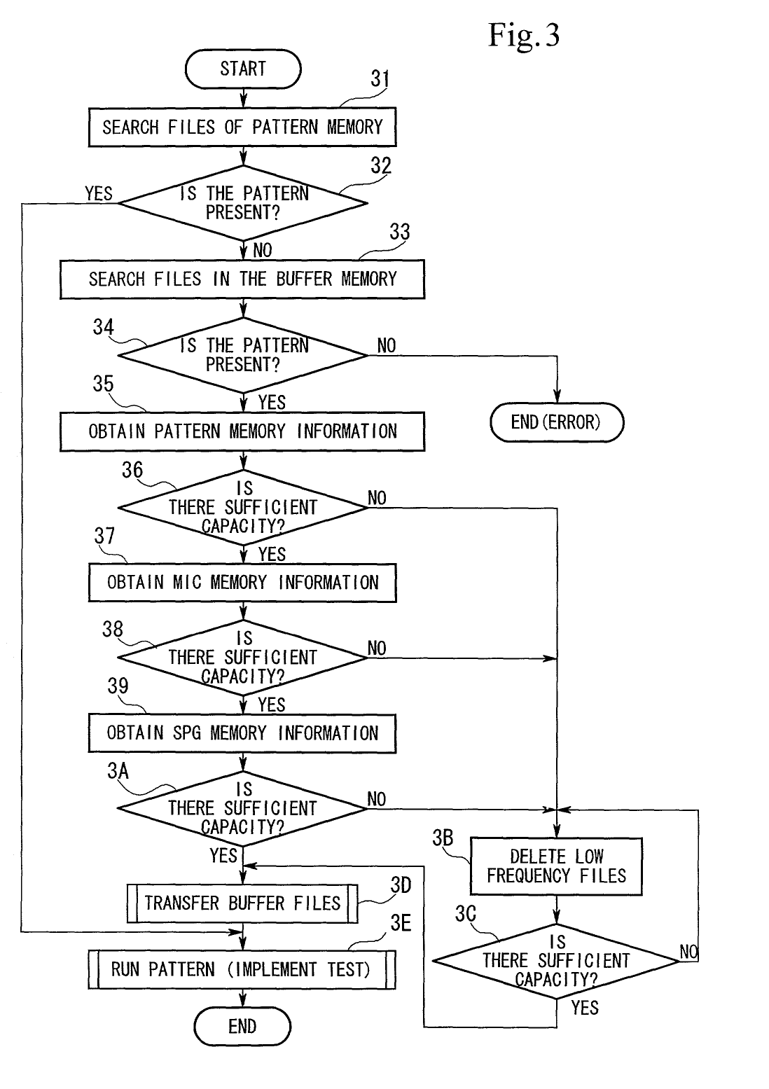

Next, an example of the operation of the embodiment will be explained referring to FIG. 1, FIG. 2, and FIG. 3.

First, referring to FIG. 2, the operation of the steps up to the point that the pattern file use frequency table has been completed and the pattern files have been optimally distributed will be explained. FIG. 2 is a flowchart showing an example of the operation of the steps up to the point that the pattern file use frequency table has been completed and the pattern files have been optimally distributed.

In step 21, the control unit 10 initializes the pattern memory 13 and each of the memories in the executive memory 17, and the pattern file use frequency table. In addition, the control unit 10 reads out all of the pattern files to be used in the test of a semiconductor that is the test object from the disk apparatus 12, and stores the pattern files that have been read out in the buffer memory 13.

In addition, the control unit 10 distributes to each memory of the executive memory 17 the pattern files that can be accommodated in the capacity of the executive memory 17, that is, the pattern files that can be stored in the executive memory 17, read out from the buffer memory 13.

Next, in step 22, the control unit 10 carries out testing of the operation of the first semiconductor based on the pattern file of, for example, pattern 1 in the specified number of semiconductors for which the pattern file use frequency will be found.

Next, in step 23, the control unit 10 uses the use frequency of the pattern file of the pattern 1 as the number of times, increments by 1 the number of times associated with the pattern file of pattern 1, and updates the contents of the pattern file use frequency table.

At this time, as shown in the pattern file use frequency table storage unit 18 of FIG. 1, the pattern file use frequency table comprises the name of the pattern file and the number of times, which shows the frequency of use of this pattern file.

Next, in step 24, because the test of the semiconductor is carried out for one semiconductor using a plurality of test items, that is, patterns files, the control unit IO determines either a pass or fail for each test item executed on the semiconductor that is the test object.

At this time, in the case that the semiconductor is determined to be defective, the control unit 10 advances the processing to step 26, and in the case that the semiconductor is not determined to be defective, that is, in the case that it is determined to be acceptable, the control unit 10 advances the processing to step 25.

Next, in step 25, the control unit 10 determines whether all of the test times for the types of semiconductor currently undergoing testing have completed, that is, whether the test using the pattern data of all the pattern files has completed.

At this time, in the case that test items remain, the control unit returns to step 22 in order to carry out testing of the next pattern file (for example, the pattern file of pattern 1).

In contrast, the control unit 10 advances the processing to step 26 in the case that it has determined that all the test items have been completed.

Next, in step 26, the control unit 10 determines whether the pattern file use frequency table has been completed.

Specifically, because the pattern file use frequency table is produced by repeating step 22 to step 25 for the preset number of semiconductors that are the test object, the control unit 10 determines whether or not the preset number of semiconductors has completed.

By this determination, it is determined whether or not the pattern file use frequency table has completed.

At this time, in the case that the control unit 10 has determined that the pattern file use frequency table has been completed, it advances the processing to step 27. In the case that it determines that the pattern file use frequency table has not been completed, it advances the processing to step 22 in order to carry out the remaining semiconductor tests.

Next, in step 27, when the pattern file use frequency table has completed, the control unit 10 initializes each of the memories of the executive memory 17 and advances the processing to step 28.

Next, in step 28, the control unit 10 reads out the pattern files from the buffer memory 13 beginning with the one having the highest use frequency in the pattern file use frequency table, and distributes (stores) them in each memory of the executive memory 17.

At this time, the storing of data in each memory of the executive memory 17 is carried out for pattern files until the free capacity of each memory in the executive memory 17 is insufficient and storage can no longer be carried out.

Thereby, the control unit 10 carries out the redistribution of pattern files arranged in each memory of the executive memory beginning with the pattern files having the highest use frequencies (the largest numbers).

Above, the pattern files are stored in the optimal sequence in each memory of the executive memory 17 while taking into account the use frequency and size.

If the tests are restarted in this condition, the pattern files having a high use frequency are already present in the executive memory 17, and the transfer time for the pattern files is reduced.

However, in the case that, as the test progresses, pattern files that cannot be stored in the executive memory must be used, in the method of the conventional technology, all of the pattern files are deleted and storing the pattern files having a high use frequency in advance depending on the pattern file use frequency table has no meaning.

In order to respond to this problem, the processing of the pattern file transfer from the buffer memory 13 to the executive memory 17 is updated by the method shown in the flowchart in FIG. 3.

In FIG. 3, steps 31 to 3A are identical to the processing content of step 51 to step 5A in the control method shown in the conventional technology.

Specifically, the processing of the present embodiment, wherein each memory in the executive memory 17 is searched, and in the case that the pattern file is not present, the relevant pattern file is transferred from the buffer memory 13 to the executive memory 17, is identical to the processing wherein the pattern memory 44, the MIC memory 45, and the SPG memory 46 in the executive memory are searched, and in the case that the pattern file is not present, the relevant pattern file is transferred from the buffer memory 13 to the executive memory 17.

The point of difference between the conventional technology and the present embodiment is that, in the case that the capacity in each memory of the executive memory 17 that is necessary for the transfer of new pattern files is insufficient, in the conventional technology, the method of initializing the entire the executive memory is used as a method for guaranteeing the capacity for transferring the pattern files, while in the present embodiment, a method of processing is used wherein the minimum free capacity necessary for the transfer is guaranteed by repeating step 3B and step 3C.

For example, in step 3A, the control unit 10 advances the processing to step 3B in the case that the capacity in each memory in the executive memory 17 necessary for transferring the new pattern files is insufficient.

Next, in step 3B, the control unit 10 deletes pattern files stored in the executive memory 17 in each memory in the order of ascending order of use frequency of the pattern files, that is, the control device deletes the pattern files stored in the part of the executive memory that stores the pattern files having the lowest use frequencies. In addition, in step 3C, the control unit 10 carries out a determination of whether or not the capacity necessary for transferring the new files has been guaranteed as a result of deleting the pattern files in the executive memory 17 having the lowest use frequencies.

At this time, the control unit 10 advances the processing to step 3D in the case that a sufficient capacity for transferring the new pattern files could be guaranteed, while in contrast, returns the processing to step 3B in the case that a capacity sufficient for transferring the new pattern files could not be guaranteed.

This means that the control unit 10 guarantees the capacity necessary for transferring the new pattern files to the executive memory by repeatedly carrying out the processing of step 3B and step 3C in the case that a sufficient capacity for transferring the new pattern files could not be guaranteed.

Next, in step 3D, the control unit 10 distributes the new pattern files necessary for the test of the semiconductor by transferring them from the buffer memory 13 to the executive memory 17.

Next, in step 3E, the control unit carries out the test based on the pattern data in the transferred pattern files after the transfer of the new pattern files necessary for the test of the semiconductor to the executive memory 17 had been completed.

According to the embodiment described above, in the case that a test of a semiconductor is carried out in a semiconductor test apparatus based on pattern data, the use frequencies of pattern data is extracted based on the results of use of a specific number of pattern data, and pattern files having pattern data are transferred from the buffer memory 13 to be stored in the executive memory 17 beginning with the pattern files having a high use frequency. Thereby, the number of times that the pattern file having the new pattern data is read can be reduced, and compared to the conventional method of the transfer processing of pattern files, the throughput of the semiconductor test can be greatly improved.

In addition, according to the embodiment described above, when newly necessary pattern files are transferred to the executive memory 17, in the case that the capacity of the executive memory 17 is insufficient, unlike the conventional technology which initializes the executive memory 17, only the pattern files stored in the part of the executive memory 17 that have a low use frequencies are deleted. Thereby, compared to initializing the executive memory 17 and transferring the new pattern files to the executive memory, the transfer time for the pattern files can be greatly reduced.

Furthermore, because the use frequency of each pattern file is carried out by sampling of the semiconductors that will actually serve as test objects, and because the use frequency of each pattern file is extracted taking into account the defect rate for each set of pattern data for each semiconductor, it can be applied to the test of a plurality of semiconductors.

In addition, the updating of the control software to attain this object is easy to maintain because it can be completed simply by updating a minimum algorithm that includes producing the pattern file use frequency table and the updating the transferred portion of the pattern files.

Above, an embodiment of the present invention was described in detail referring to the figures, but the concrete structure is not limited by this embodiment, and design modifications of the present invention are possible that do not depart from the spirit thereof.

According to the present invention, in a semiconductor test apparatus, pattern files can be stored in the executive memory beginning with those that have a high use frequency, and in the case that the capacity of the executive memory is insufficient, only pattern files in the part of the memory having the pattern files with a low use frequency are deleted.

Furthermore, the use frequency is extracted by sampling the semiconductors that are actually test objects by taking into account their defect rate, and can be applied to the testing of various semiconductors. In addition, the updating of the control software to attain this object is easy to maintain because this can be completed simply by updating a minimum algorithm that includes updating the production of the pattern file use frequency table and the transferred portion of the pattern files.

As a result, according to the present invention, in a semiconductor test apparatus, the transfer time for pattern files can be greatly reduced, and the throughput of the semiconductor testing can be greatly increased.

What is claimed is:

1. A semiconductor test apparatus that tests the operation of a semiconductor based on a plurality of pattern data, comprising:
a counter device that counts the number of times pattern data is used for each of said pattern files; and
a control unit that produces a pattern file use frequency table showing the relationship between each of said files and said number of times the files are used, and stores this pattern file use frequency table in the memory.

2. A semiconductor test apparatus according to claim 1 wherein said counting device counts the number of times said pattern data is used in a set of test for a predetermined number of semiconductors.

3. A semiconductor test according to claim 1, wherein said control unit rearrange the pattern files in descending order of frequency of use based on said pattern file use frequency table after producing said pattern file use frequency table.

4. A semiconductor test apparatus according to claim 1, wherein said control unit deletes the pattern files in ascending order of frequency of use in the case that the capacity of the executive memory is insufficient when transferring said pattern files to the executive memories.

5. A control method of the semiconductor test apparatus that tests the operation of a semiconductor based on a plurality of pattern data, comprising the steps of:
counting the number of times said pattern data is used for each pattern file; and
preparing a pattern file use frequency table that shows the relationship between each file and the number of times these files are used, and storing this pattern file use frequency table in the memory.

6. A control method of the semiconductor test apparatus according to claim 5, wherein, in said counting step, the number of times said pattern data is used in a set of test for a predetermined number of semiconductors is counted.

7. A control method of the semiconductor test apparatus according to claim 5, wherein said storing step stores the pattern files in descending order of frequency of use based on said pattern file use frequency table after producing said pattern file use frequency table.

8. A control method of the semiconductor test apparatus according to claim 5, wherein said storage step deletes the pattern in ascending order of frequency of use in the case that the capacity of the executive memory is insufficient when transferring said pattern files to the executive memories.
